(19) United States
(12) Patent Application Publication
(10) Pub. No.: US 2016/0343513 A1
(43) Pub. Date: Nov. 24, 2016

(54) PATTERNED ELECTRODE CONTACTS FOR OPTOELECTRONIC DEVICES

(71) Applicant: TOYOTA MOTOR EUROPE NV/SA, Brussels (BE)

(72) Inventors: Sachin KINGE, Brussels (BE); Enrique CANOVAS DIAZ, Mainz (DE); Mischa BONN, Frankfurt Am Main (DE)

(73) Assignee: TOYOTA MOTOR EUROPE NV/SA, Brussels (BE)

(21) Appl. No.: 15/112,349

(22) PCT Filed: Feb. 6, 2014
(86) PCT No.: PCT/EP2014/052358

§ 371 Date: Jul. 18, 2016

(51) Int. Cl. H01G 9/20; H01L 51/44; H01L 51/42

(52) U.S. Cl. CPC H01G 9/209; H01L 51/426; H01L 51/447

(57) ABSTRACT

A micropillar array structure includes a substrate; and an array of micropillars provided on a surface of the substrate, wherein the micropillars are substantially transparent to light, and the height of micropillars is at most 500 μm. The micropillar array structures can be used in optoelectronic devices such as solar cells.

### FIELD OF THE INVENTION

The present invention relates to patterned electrode contact surfaces that can be used in various optoelectronic devices.

### BACKGROUND TO THE INVENTION

Common optoelectronic devices include sensors and solar cells. As regards solar cells for practical use, one may consider that in the “first generation” of devices, thick single crystalline forms of silicon have been used.

By differential doping to create a p-n junction, photoelectric conversion efficiencies of 30% are theoretically possible, and some systems developed show efficiencies up to 25%. In a “second generation” of products that have recently become available, thinner films (with thicknesses typically in the 150 to 180 μm range) have been developed, which may use silicon, or other semiconducting material such as cadmium telluride (CdTe). Similar efficiencies are potentially available. The theoretical limit is identical for thin films. Another example of 2^{nd} generation product is a dye-sensitized solar cell (DSC). In the development of a “third generation” of products (with efficiencies post 30% as defined by SQ limit), one approach that has been explored is the use of nanoparticle semiconductor oxides (typically titanium dioxide). Another approach is to produce a “tandem” structure with a stack of very thin layers, an approach which could in principle lead to higher conversion efficiencies.

As examples of various optoelectronic devices, reference may be made to attached FIGS. 1 to 4. These Figures show, respectively, a QDLED device (quantum dot light-emitting diode), a QD n-p type solar cell, an infra-red photo detector for a camera, and a QD sensitized solar cell.

As an example, in a typical thin film excitonic solar cell, there may be a transparent front electrode, typically glass coated with a transparent conducting oxide (TCO), and a back electrode, and sandwiched between the two, titanium oxide (TiO₂) (nano)particles coated with an organic dye which may absorb incoming light radiation, with the production of electrons in an excited state. Electrons may be transferred through semiconducting nanoparticles to reach one electrode whilst electrons are produced, coming from the other electrode, to occupy holes, most commonly through an electrolyte such as the I⁻/I₃⁻ couple. In such a system, electrons, or holes, may “recombine” with an opposite charge carrier in the interface between contacts, before reaching the electrode, so that the conversion efficiency, of light energy into electric current, is degraded. The process of diffusion through the nanoparticle is thus inherently linked to a loss in conversion efficiency. This type of problem is relevant for various types of optoelectronic device with a diffusion limited transport problem, for example sensitized solar cells (based on dyes, or inorganic nanoparticles, or thin film semiconductors etc.), and also bulk hetero-junction organic solar cells, organic light-emitting diodes (OLED) etc.

The “diffusion length” Lₑ is the average distance a carrier (a free electron or hole) can move in any direction inside the transporting carrier material before it recombines with an opposite charge carrier. The carrier transporting medium thickness, if high conversion efficiency is to be maintained, is limited by this length. In any device, the diffusion length Lₑ should ideally be greater than the thickness of the carrier transporting medium. However, the absorber thickness T determines in many cases, such as sensitized solar cells, the light absorption efficiency as a function of the wavelength and thereby the overall solar cell device efficiency. In practice, the diffusion length of the carrier is always very small compared with the thickness of the absorber required for complete absorption of light. Put simply, although in typical circumstances, several hundred micrometres (μm) of thickness of photo-absorbing material may be required for complete absorption of light in a solar cell or other analogous optoelectronic device, the diffusion length being more commonly of the order of only a micro-meter or a few micrometres, losses are inevitable.

As a case example in optimized dye solar cells, efficiency measurements on complete devices for a TiO₂-N₃ dye-iodine electrolyte indicate that the optimum thickness is around 10 microns. A thickness of 10-12 microns has been reported to be optimum for this system (this is due to diffusion length constraints), but that value makes absorption between 600 and 800 nm weak (photocurrent is lost just due to the thickness of the cell).

In US 2011/0232759, dye-sensitised solar cells are described containing an anode with a micro-textured electron-collecting structure such as micropillars of nickel (Ni) metal. The micropillars may in particular be arranged in a square lattice on an FTO (fluorine-doped tin oxide F:SnO₂) glass conductor substrate. The solar cells of US 2011/0232759 can further include Pt-coated nanoporous anodised aluminium oxide (AAO) placed directly on the TiO₂ layer to serve as cathode. By this means, it is considered that electron and hole transport distances will be reduced.

However, for solar cell applications, maximum light collection with minimal shadowing losses are required, and the materials as well as geometrical structure proposed in US 2011/0232759 may not be optimal in this respect. Nickel (Ni) metal pillars may generate big shadowing factors and solar cell reflection losses (which are more pronounced at tilted solar irradiation angles). Furthermore, the squared pattern is not ideal for minimum shadowing in the cell (a minimum number of pillars per unit area is desired), the pillar pitch (separation between pillars) is not apparently designed according to physical constraints such as the diffusion length and accordingly, it is believed, part of the pillars will not contribute to better collection but only to increased shadowing.

### SUMMARY OF THE INVENTION

In the present invention, the inventors have sought to create a basis for forming optimum micropillar structures vis-à-vis the material as well as the dimensions in order to reduce the diffusion limitation without changing the diffusion length of the carriers in a given transporting medium.

In the case of devices requiring light to pass through the active carrier transporting media, like solar cells, the electrode compatible structures created by the present inventors, and which are transparent to the light, may help to reduce the losses in light absorption caused by metallic nanostructures or non-transparent materials in general.

Further, the structures created can be molded in different shapes to optimize maximum absorption by light trapping schemes (which improves efficiency and saves costs).

The optimum geometry described overcomes the shadowing effect inherent in earlier systems. In an optimal configuration, the micropillars are designed in a hexagonal arrangement with an inter-micropillar distance equal to at most twice the diffusion length within the active absorber material. This can reduce the non-light active material content in the device, hence increasing the space for the light sensitive material.

The structures of the invention can also be designed for internal light reflection to enhance further light absorption, similar to plasmonic structures.

In one aspect therefore, the present invention relates to a micropillar array structure comprising:

a substrate; and

an array of micropillars provided on a surface of the substrate, wherein:

the micropillars are substantially transparent to light, and

the height of micropillars is at most 500 μm.

In another aspect, the invention relates to an optoelectronic device comprising such a micropillar array structure.

### BRIEF DESCRIPTION OF THE FIGURES

FIGS. 1 to 4 show conventional formats of, respectively, a QDLED device (quantum dot light-emitting diode), a QD n-p type solar cell, an infra-red photo detector for a camera, and a QD sensitized solar cell.

FIG. 5a shows an illustrative hexagonal arrangement of micro-pillars in an array, wherein the micro-pillars have a circular cross-section of diameter S (which should be minimized while preserving pillar robustness), and the inter-micropillar distance d is equal to twice the diffusion length (2L). In this hexagonal arrangement, each micro-pillar has six closest micro-pillars around it, disposed so that the centres of the six surrounding micro-pillars constitute the vertices of a regular hexagon.

FIG. 5b shows part of an illustrative micro-pillar array from a side view, where the height of micro-pillars is l and the inter-pillar distance d is 2L—here L refers here to diffusion length of carriers in the active material.

FIG. 6 shows a side view of a micro-pillar array where the micro-pillars are conical or pyramidal. The distance d between adjacent micro-pillar central axes, or between adjacent peak tops, is d, which in this illustrative examples is set equal to 2L.

FIG. 7 shows an illustrative interdigitated array system, where a micro-pillar array according to the invention on the anode is interdigitated with an array on the cathode.

FIG. 8 shows a scanning electron microscopy (SEM) image of an illustrative regular micro-pillar array according to the invention, shown in higher definition in FIG. 9.

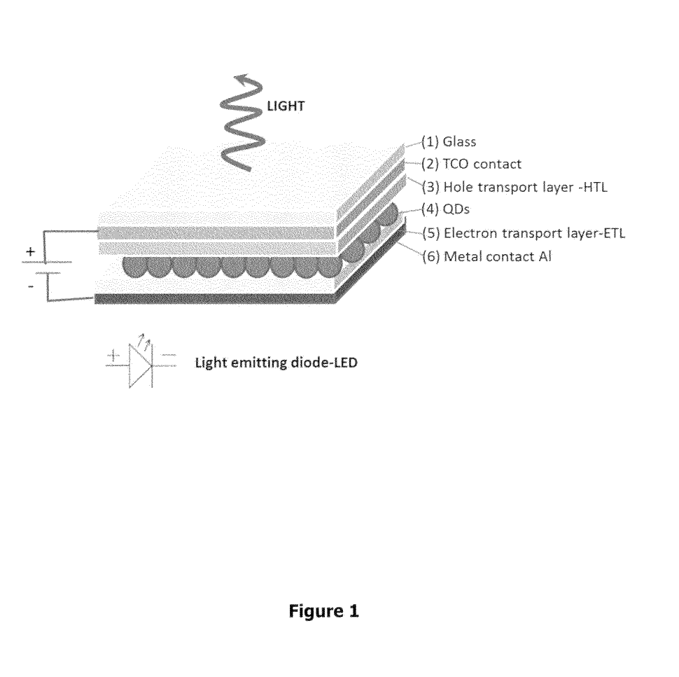

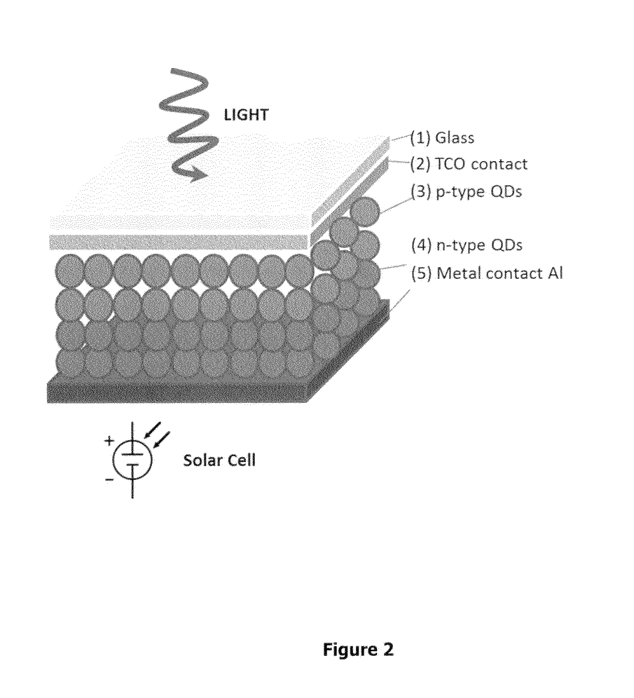

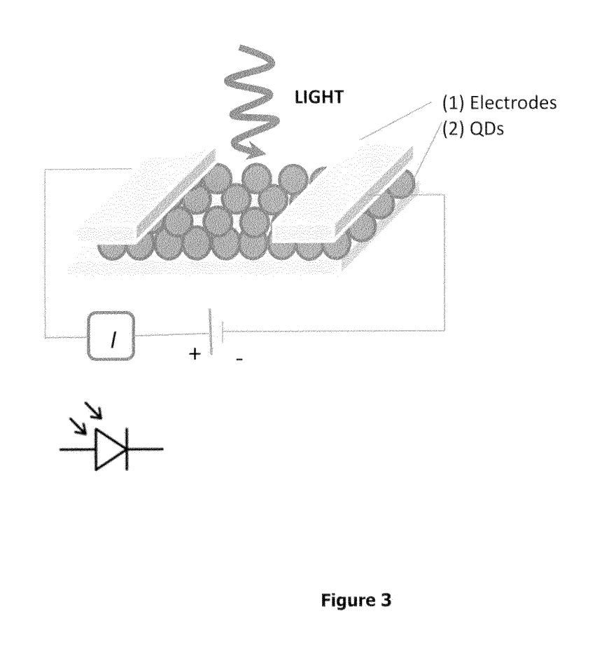

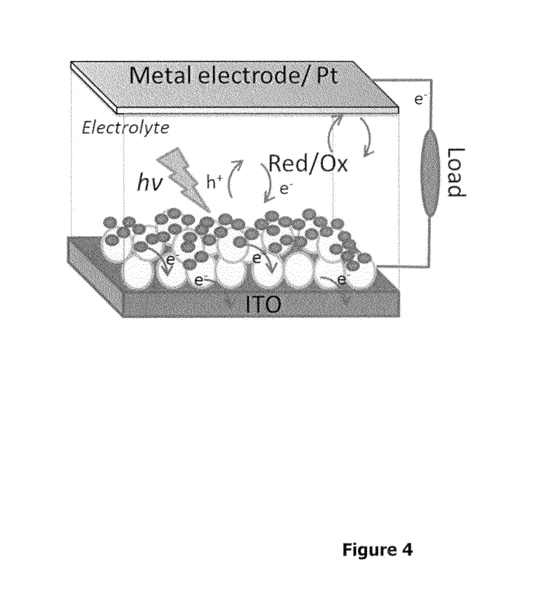

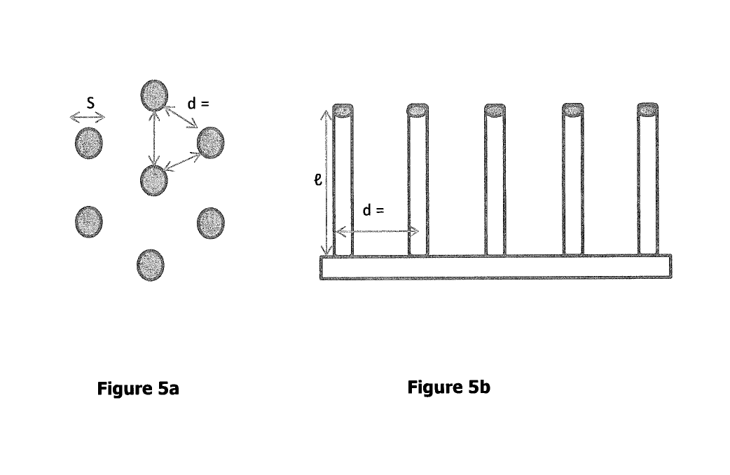

### DETAILED DESCRIPTION OF THE INVENTION

For a dye solar cell (or any sensitized solar cell), to absorb all the visible light, one typically needs a thickness of active material of a few hundred microns. However, the carriers (electron and holes) cannot travel such long distances (the maximum distance travelled is usually just a few microns or even nanometers). Electrodes should thus, as far as practicable, be close enough to point of generation of carriers due to light excitation. In thick films, e.g. a few hundred micrometers, this is impossible if the contacts are at the end. However, in the present invention, the thickness can be increased by using pillar-like electrodes. Here diffusion length is no more a major issue as the inter-pillar spacing may be chosen to be of the same order as, or even less than, the diffusion length.

In the production of a typical micropillar array according to the present invention, the collecting patterns may be prepared from transparent materials such as epoxy resins or any other material that shows transparency as well properties to create moulds for subsequent electrode pattern creation and which is also compatible with the electrode materials. An illustrative example of such a material is an epoxy resin mould material such as SU-8 epoxy resin (reported in J. Micromech. Microeng., 7 (1997) 121). Using masking and photolithography techniques, an organic resin such as an epoxy resin can be moulded to produce a pillar array of the required size. More generally, other photoresist organic resin materials known in the art can be used, such as poly(methyl methacrylate) (PMMA), poly(methyl glutarimide) (PMGI), or phenol formaldehyde resins such as DNQ/Novolac. In processes of the invention using such materials, a photolithography step will also be present, and moulds can be used to create patterns. It is also possible for a glass micropillar array to be used in the present invention, although this is more difficult in view of the difficulty in controlling etching of glass.

In the creation of a micropillar array, a pattern may be created using a mask with the negative shapes of future micropillars, e.g. of organic resin, with aspect ratios and pitch values. The diameters of micropillars should be as small as possible. In a generally favourable embodiment, the inter-micropillar distances (pitch values) are maintained equal to or less than twice the diffusion length of the carrier to be collected. Advantageous ranges of micro-pillar density on the surface of the substrate may vary depending upon the materials used. As an example, for a N₃+TiO₂ solar cell, the distance between pillars should preferably be around 20 microns. The density of micropillars on the surface would thus be around roughly 12 micropillars/(80×40 μm)².

Using photolithographic techniques, micropillar diameters of 15/20 nm can be achieved.

In advantageous embodiments, organic resin micropillar materials such as epoxy moulds, which may be created on glass or other supporting substrates, may be coated with a transparent metal contact (as ITO or FTO). The latter will be transparent for solar cell applications.

Concerning possible substrate materials to support micropillar arrays according to the invention, in principle any substrate material could be used so long as it is transparent (or substantially transparent) to solar radiation—the light should reach the cell from the micropillar textured side. Typical materials used in the art include conductive oxides, in some cases conductive plastic; metals are also used as thin foils. Glass is also a preferred embodiment for a substrate material according to the present invention.

The micropillars alone are not themselves photo-active, though they must be substantially or fully transparent (to light). The micropillars may be seen as a textured substrate surface where one may place a photo-converter system (an example would be: ITO+dye+oxide+electrolyte). Through the system of the present invention, it is intended to allow thicker layers of photo-active materials to be employed and enhanced photo-current (and efficiency) is thereby expected.

Examples of oxide materials that may be used in systems of the present invention include ones selected from the group consisting of: TiO₂, ZnO, SnO₂, PbO, WO₃, SrTiO₃, BaTiO₃, FeTiO₃, MnTiO₃, Bi₂O₃, Fe₂O₃.

Examples of dye materials that may be used in systems of the present invention include ones selected from the group consisting of: Ru535, Ru535-bisTBA, Ru 620-1H3TBA, Ru 520-DN, Ru 535-4TBA, Ru 455-PF6, Ru 470, Ru 505, SQ2, rylene dyes.

In the present invention, the maximum height of micropillars is about 500 μm. The most appropriate minimum and maximum heights for micropillars are difficult to quantify in a general manner since these values intrinsically depend on the nature of the absorber material and the wavelengths to be absorbed. An appropriate height for micropillars will typically be one allowing full light absorption above the active material bandgap (this will be given by the absorption coefficient (cm⁻¹) of the active photo-absorber at the LUMO (CB) energy). Ideally, the diameter of micropillars should be reduced to a minimum whilst being sufficiently robust. In some practical embodiments, micropillars may have a diameter in the micrometre range, e.g. from 0.5 to 50 μm. Nanometer range diameter micropillars are also possible, e.g. from 10 to 500 nm. The micropillar diameter in this context is to be measured at the base of the micropillar (point of contact with the underlying substrate) for a tapering cone-shaped micropillar, or other micropillar whose cross-sectional shape and area are not constant.

In the present invention, the inter-micropillar distance is not more than twice the diffusion length within the photo-active material (used in an optoelectronic device), which may typically be a mesoporous oxide sensitized by a dye. The diffusion length depends on the lifetime and mobility of carriers. Carrier mobility is commonly measured by methods known in the art through the Hall effect. The lifetime can be measured by ultrafast spectroscopy (i.e. THz-TDS—Terahertz time-domain spectroscopy). As explained, optimal inter-micropillar distances depend on the properties of the materials used in the photo-active material, and so most appropriate ranges are difficult to quantify in a general manner. However, in some advantageous embodiments, inter-micropillar distances may be in the range of 1 to 50 μm, preferably 5 to 25 μm.

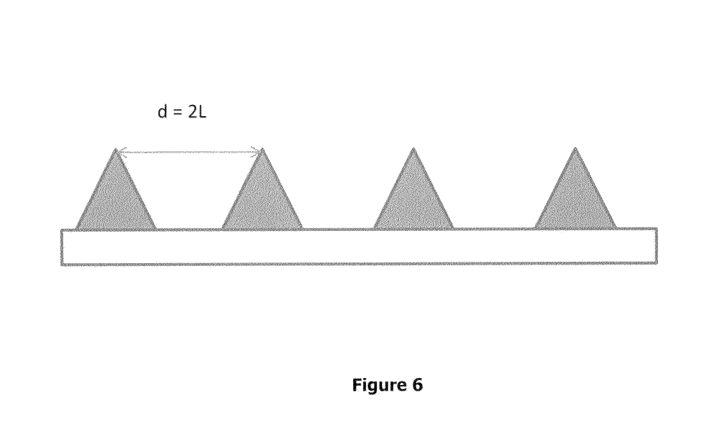

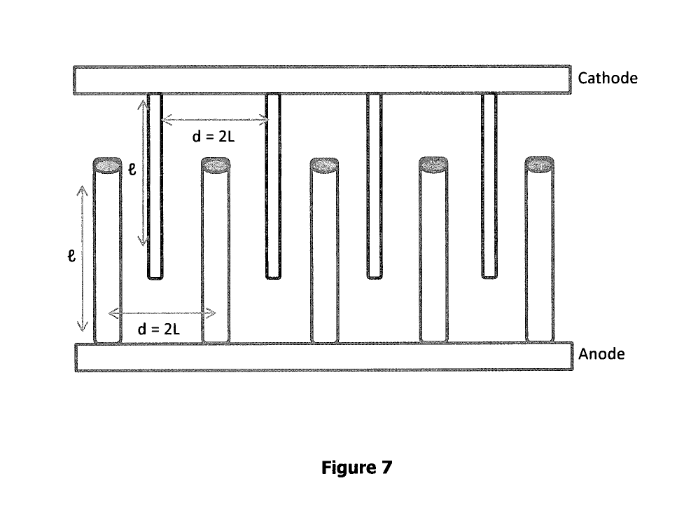

It is also contemplated within the present invention to have interdigitated geometries. Namely, the hole collecting collector can be also shaped with electrode projections penetrating the electron conductor as shown in FIG. 7. The micropillars can be cylinders, or have a conical or pyramidal shape (FIG. 6). The latter two types of design could be useful also as an antireflection coating or further support multiple reflection.

In addition, in a preferred embodiment of the present invention, stacks of micro-pillar arrays according to the invention could be used to produce a “tandem” structure. The material of the micro-pillars, and any coating material thereof, in successive layers of a stack may or may not be the same from one layer to the next. In a preferred embodiment of a “tandem” structure, the micro-pillars in successive layers would be vertically aligned.

Within the practice of the present invention, it may be envisaged to combine any features or embodiments which have hereinabove been separately set out and indicated to be advantageous, preferable, appropriate or otherwise generally applicable in the practice of the invention. The present description should be considered to include all such combinations of features or embodiments described herein unless such combinations are said herein to be mutually exclusive or are clearly understood in context to be mutually exclusive.

### EXPERIMENTAL SECTION—EXAMPLES

The following experimental section illustrates experimentally the practice of the present invention, but the scope of the invention is not to be considered to be limited to the specific examples that follow.

According to one embodiment, the following protocol was used to prepare a micro-pillar structure. Here, the micropillars are all part of an original single monolithic block of SU-8 epoxy resin, the spaces between the pillars being removed during the process. The steps of this illustrative process were as follows:

1—Substrate-glass slide cleaning: (distilled water+acetone+isopropanol)

2—Lack (SU 8) coating: deposition of 1 ml lack/inch² followed by a spinning recipe (500 rpm (10 s)/acceleration 100 rpm/s+2000 rpm (30 s)/acceleration 200 rpm/s). Removal of lack excess on the edges with knife.

3—Soft bake treatment: 3.5 min on hot plate (90° C.)

4—Exposure: 140 mJ/cm² of UV light (>350 nm). For the mask aligner used, 10 s exposure.

5—Post bake: 3.5 min on hot plate (90° C.)

6—Development: immersion of substrate+exposed lack in SU-8 developer (MICRO-CHEM) for 3.5 minutes.

7—Cleaning: Isopropanol bath and drying with N₂ gun.

8—Hard bake: 30 min on hot plate (300° C.)

Step 8 was followed by deposition of ITO by pyrolysis, using spray coating to give a coat less than 100 nm. Any material can be deposited which is suitable for carrier extraction e.g. inorganic materials such as TiO₂, ZnO, SnO, or conducting organic polymer materials. The inorganic oxides such as ITO, TiO₂, ZnO and SnO are in practice transparent until functionalized by a dye. Oxide particles should preferably be used with a particle below about 50 nm, otherwise the oxides tend to look white due to light scattering in the visible range.

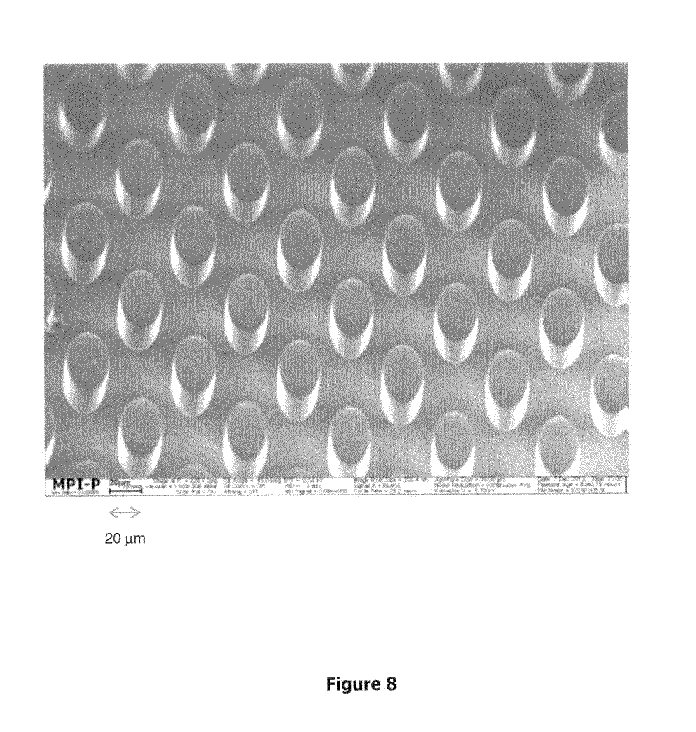

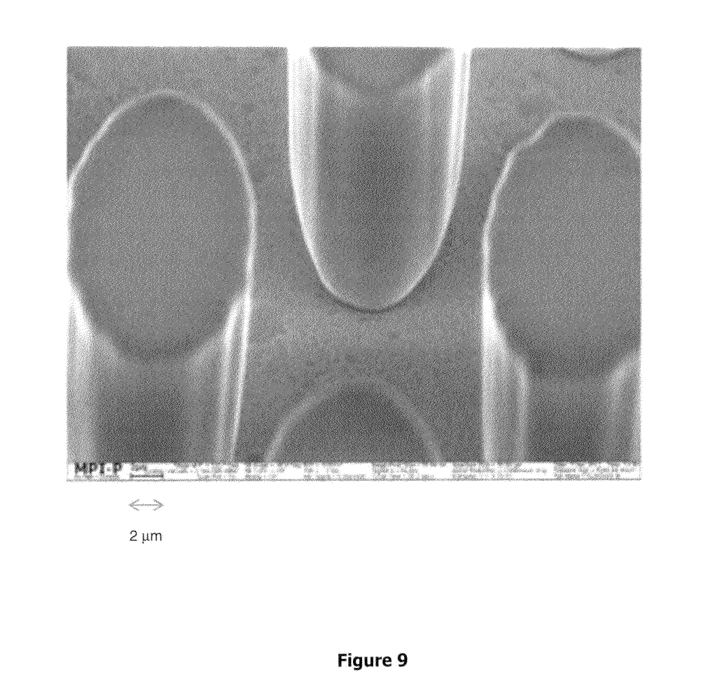

A regular micro-pillar array obtained by the above method, and observed by scanning electron microscopy (SEM) is shown in FIG. 8, and in higher definition in FIG. 9.

1-10. (canceled)

11. Optoelectronic device comprising a micropillar array structure, the micropillar array structure comprising:
a substrate; and
an array of micropillars provided on a surface of the substrate, wherein:
the micropillars are substantially transparent to light, and
the height of micropillars is at most 500 μm, wherein each micropillar is surrounded by neighbouring micropillars in the array in a hexagonal arrangement.

12. An optoelectronic device according to claim 11, wherein the micropillars have a cylindrical, pyramidal or conical shape.

13. An optoelectronic device according to claim 11, wherein the micropillars are made of organic polymer resin or glass.

14. An optoelectronic device according to claim 11, wherein the surface of the micropillars is coated with a transparent conductive material selected from the group consisting of: ITO, FTO, and graphene.

15. Optoelectronic device according to claim 11, which further contains a photo-active material.

16. Optoelectronic device according to claim 15, wherein the photo-active material is a mesoporous oxide sensitized with a dye.

17. Optoelectronic device according to claim 15 wherein the inter-micropillar distance is not more than twice the diffusion length within the photo-active material.

18. Optoelectronic device according to claim 15, wherein the optoelectronic device is a solar cell.
